(19) United States
(12) Patent Application Publication
(10) Pub. No.: US 2025/0221034 A1
(43) Pub. Date: Jul. 3, 2025

(54) SEMICONDUCTOR DEVICE WITH DELAY CIRCUITS IMPLEMENTED BY REUSING OXIDE DIFFUSION EDGE DUMMY GATES

(71) Applicant: MEDIATEK INC., Hsinchu City (TW)

(72) Inventors: Hung-Yi Huang, Hsinchu City (TW); Wei-Te Lin, Hsinchu City (TW); Wei-Hsin Tseng, Hsinchu City (TW)

(73) Assignee: MEDIATEK INC., Hsinchu City (TW)

(21) Appl. No.: 19/002,729

(22) Filed: Dec. 27, 2024

Related U.S. Application Data
(60) Provisional application No. 63/614,960, filed on Dec. 27, 2023.

(51) Int. Cl. H10D 84/90; H03M 1/66

(52) U.S. Cl. CPC H10D 84/925; H03M 1/66

(57) ABSTRACT

A semiconductor device includes an oxide diffusion (OD) area; at least one first poly gate, formed above the OD area; and a plurality of second poly gates, formed on both sides of the at least one first poly gate and above the OD area. The plurality of second poly gates are OD edge dummy gates that are used to reduce length of oxide diffusion (LOD) effect, and at least a portion of the plurality of second poly gates are reused to implement at least one delay circuit.

### CROSS REFERENCE TO RELATED APPLICATIONS

This application claims the benefit of U.S. Provisional Application No. 63/614,960, filed on Dec. 27, 2023. The content of the application is incorporated herein by reference.

### BACKGROUND

The present invention relates to an integrated circuit design, and more particularly, to a semiconductor device with delay circuits (e.g., tunable delay circuits for skew calibration) implemented by reusing oxide diffusion (OD) edge dummy gates.

The evolution of advanced complementary metal-oxide-semiconductor (CMOS) processes has pushed the boundaries of analog and mixed-signal design towards high-fidelity and high-accuracy implementations while maintaining high-speed operation. Despite digital processing advancements and signal integrity advantages, real world signals are inevitably analog. Thus, high-speed digital-to-analog converters (DACs) are developed to enable the link between analog and digital domains. The data fidelity and accuracy in mixed-signal circuits can be compromised when attempting to increase the data rate of the circuit close to its bandwidth. To surpass the data rate limits, a time-interleaved design technique is introduced and applied to DACs.

A time-interleaved DAC includes a plurality of sub-DACs, each operating at a lower sampling rate. The sub-DACs are controlled by phase-shifted clocks, which results in time-shifted contribution to an analog output signal of the time-interleaved DAC. The main advantage of the time-interleaved DAC is that, due to the phase-shifted signals, the analog output signal seems to be generated at a higher sampling rate. Taking a two time-interleaved current-steering DAC for example, it may include two sub-DACs placed in parallel, where each of the sub-DACs outputs its current to an output and an identical dummy output alternatively. Specifically, when one of the sub-DACs is connected to the output, the other of the sub-DAC is connected to the dummy output. The switching timing of each sub-DAC between the output and the dummy output is critical to the performance of the two time-interleaved current-steering DAC.

A sub-DAC may include DAC cells for dealing with digital-to-analog conversion of a most significant bit (MSB) segment, DAC cells for dealing with digital-to-analog conversion of an upper significant bit (USB) segment, and DAC cells for dealing with digital-to-analog conversion n of a least significant bit (LSB) segment. The numbers of DAC cells allocated for different segments may be different. Hence, switch drivers of DAC cells allocated for different segments may have different loads. In addition, layout locations of switch drivers and switches included in DAC cells for one segment may be different from that of switch drivers and switches included in DAC cells allocated for another segment. Due to these factors, skew is induced between switching timing of DAC cells allocated for different segments.

Thus, there is a need for a low-cost, area-efficient delay circuit design to address a skew issue encountered by a circuit such as a DAC.

### SUMMARY

One of the objectives of the claimed invention is to provide a semiconductor device with delay circuits (e.g., tunable delay circuits for skew calibration) implemented by reusing oxide diffusion (OD) edge dummy gates.

According to an aspect of the present invention, an exemplary semiconductor device is disclosed. The exemplary semiconductor device includes a first OD area; at least one first poly gate, formed above the first OD area; and a plurality of second poly gates, formed on both sides of the at least one first poly gate and above the first OD area, wherein the plurality of second poly gates are OD edge dummy gates that are used to reduce length of oxide diffusion (LOD) effect, and at least a portion of the plurality of second poly gates are reused to implement at least one first delay circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a top view of an exemplary layout design of a semiconductor device according to an embodiment of the present invention.

FIG. 2 is a diagram illustrating a tunable delay circuit that is implemented using OD edge dummy gates and employs a gate delay tuning technique according to an embodiment of the present invention.

FIG. 3 is a diagram illustrating a tunable delay circuit that is implemented using OD edge dummy gates and employs a capacitive load tuning technique according to an embodiment of the present invention.

FIG. 4 is a diagram illustrating a first capacitive load tuning design according to an embodiment of the present invention.

FIG. 5 is a diagram illustrating a second capacitive load tuning design according to an embodiment of the present invention.

FIG. 6 is a diagram illustrating a DAC cell that receives control signals with tunable delays set by tunable delay circuits implemented using OD edge dummy gates according to an embodiment of the present invention.

FIG. 7 is a top view of a layout design of RZ switches and tunable delay circuits shown in FIG. 6.

FIG. 8 is a diagram illustrating a sub-DAC with tunable delay circuits implemented using OD edge dummy gates according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

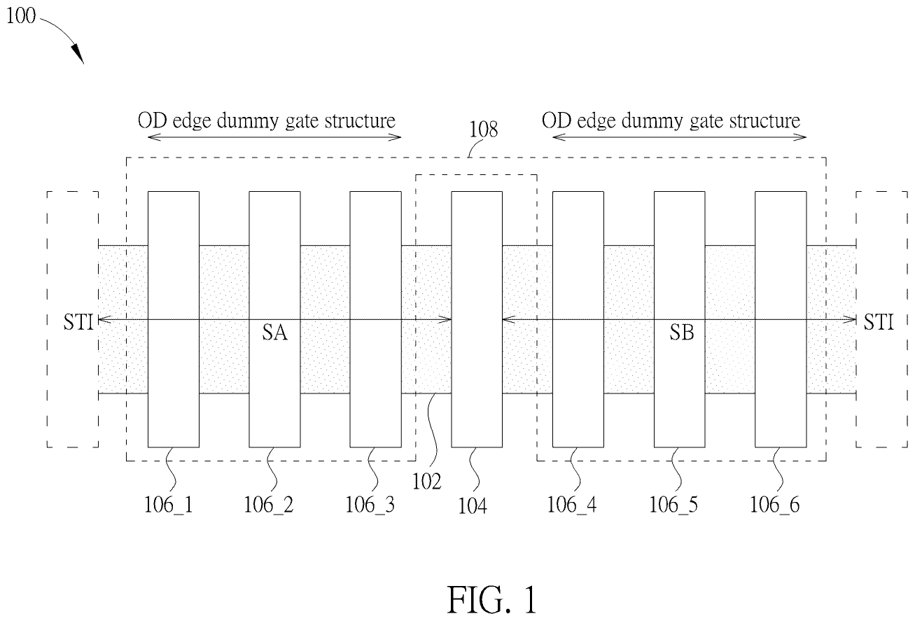

FIG. 1 is a diagram illustrating a top view of an exemplary layout design of a semiconductor device according to an embodiment of the present invention. The semiconductor device 100 includes a plurality of oxide diffusion (OD) areas, each defining diffusion of an active area (i.e., transistors' sources and drains). However, due to shallow trench isolation (STI) used in the semiconductor device 100, STI at an edge of the OD area causes mechanical compressive stress, and the stress increases as a channel of a critical device to an STI/OD edge distance SA/SB decreases. Specifically, the length of oxide diffusion (LOD) reflects the distance from the channel to the stress source, and the STI induced stress has impact on device performance such as the threshold voltage. Typically, OD edge dummy gate(s) (i.e., dummy device(s)) can be added to reduce the LOD effect. The semiconductor device 100 is shown having an OD area 102 and a plurality of poly gates 104, 106_1, 106_2, 106_3, 106_4, 106_5, 106_6, where the poly gate 104 formed above the OD area 102 is used by a critical device (e.g., a MOS switch), and poly gates 106_1-106_6 formed on both sides of the poly gate 104 and above the OD area 102 are OD edge dummy gates that are used to reduce LOD effect resulting from STI on edges of the OD area 102. In this embodiment, at least a portion (i.e., part or all) of the poly gates (OD edge dummy gates) 106_1-106_6 are reused to implement one or more delay circuits 108. For example, the poly gates (OD edge dummy gates) 106_1-106_3 on the left side of the poly gate 104 used by the critical device may be reused to implement one delay circuit, and the poly gates (OD edge dummy gates) 106_4-106_6 on the right side of the poly gate 104 used by the critical device may be reused to implement another delay circuit. In some embodiments of the present invention, the delay circuit(s) 108 may include one or more tunable delay circuits that can be used to address a skew issue of a signal supplied to the poly gate 104 used by the critical device (e.g., MOS switch). In other words, the poly gates (OD edge dummy gates) 106_1-106_6 can be used to achieve skew calibration while reducing the LOD effect that causes performance degradation of the critical device (e.g., MOS switch). Since the OD edge dummy gates are reused to implement the tunable delay circuits, there is no any area overhead for the tunable delay circuits.

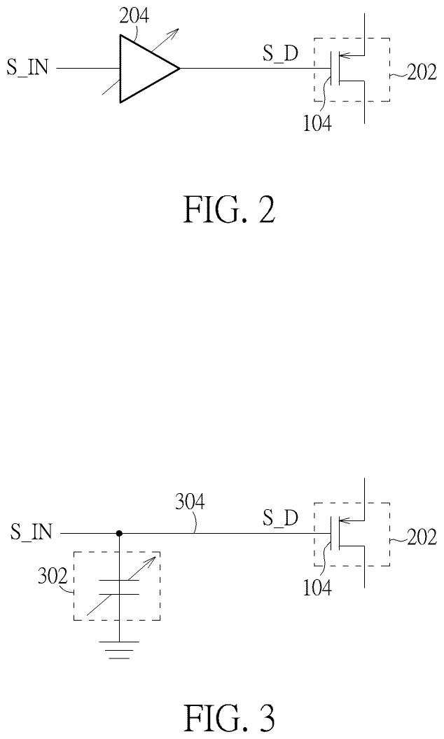

In some embodiments of the present invention, the delay circuit(s) 108 implemented by reusing the poly gates (OD edge dummy gates) 106_1-106_6 may include one or more tunable delay circuits each using a gate delay tuning technique, as illustrated in FIG. 2. A delay circuit 108 may be implemented using a tunable delay circuit 204 shown in FIG. 2. The poly gate 104 may be a gate terminal of a MOS transistor 202 (which may act as a MOS switch), and a source terminal and a drain terminal of the MOS transistor 202 may be contacts formed on source/drain regions in the OD area 102. The tunable delay circuit 204 is used to delay an input signal S_IN to generate a delayed signal S_D, and the delayed signal S_D is received by the MOS transistor 202. In accordance with the gate tuning technique, the tunable delay circuit 204 may include logic gate(s) for processing the input signal S_IN, and the delay applied to the input signal S_IN may be controlled by tuning the gate delay possessed by the logic gate(s).

In some embodiments of the present invention, the delay circuit(s) 108 implemented by reusing the poly gates (OD edge dummy gates) 106_1-106_6 may include one or more tunable delay circuits each using a capacitive load tuning technique, as illustrated in FIG. 3. A delay circuit 108 may be implemented using a tunable delay circuit 302 shown in FIG. 3. The poly gate 104 may be a gate terminal of the MOS transistor 202 (which may act as a MOS switch), and a source terminal and a drain terminal of the MOS transistor 202 may be contacts formed on source/drain regions in the OD area 102. The tunable delay circuit 302 is used to delay an input signal S_IN to generate a delayed signal S_D, and the delayed signal S_D is received by the MOS transistor 202. The tunable delay circuit 302 may provide a capacitive load to a signal line 304 on which the input signal S_IN is transmitted, and the delay applied to the input signal S_IN is controlled by tuning the capacitance value of the capacitive load.

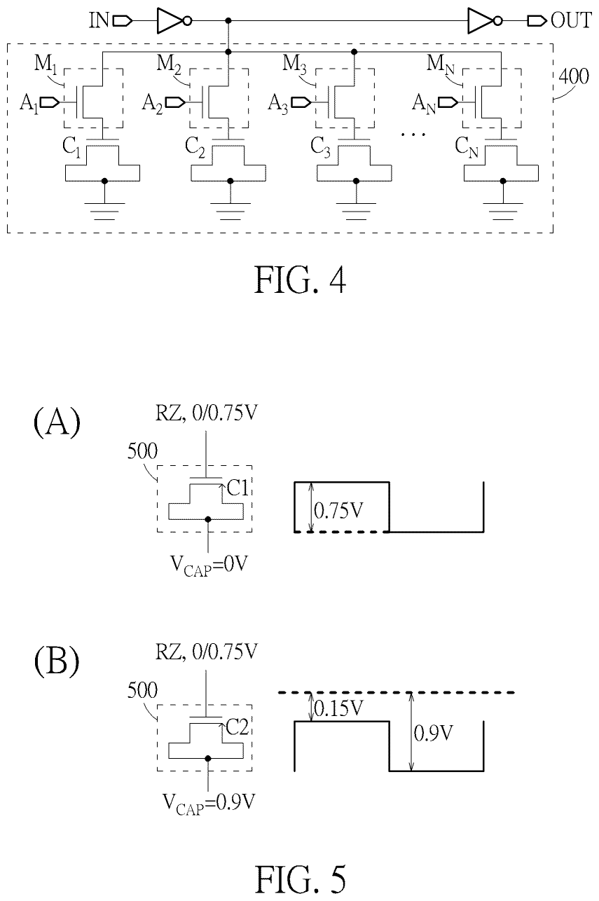

FIG. 4 is a diagram illustrating a first capacitive load tuning design according to an embodiment of the present invention. The tunable delay circuit 302 shown in FIG. 3 may be implemented using the capacitive load tuning circuit 400 shown in FIG. 4. The capacitive load tuning circuit 400 may include a plurality of MOS capacitors C₁, C₂, C₃, . . . , C_{N} and a plurality of MOS switches M₁, M₂, M₃, . . . , M_{N}. The MOS switches M₁-M_{N} are connected to the MOS capacitors C₁-C_{N}, respectively. It should be noted that one end of a MOS capacitor is connected to a reference voltage (e.g., ground voltage), and the other end of the MOS capacitor is connected to a signal to be delayed (which is not a reference voltage such as a power supply voltage or a ground voltage) when an associated MOS switch is turned on. The MOS switches M₁-M_{N} are controlled by a plurality of control signals A₁, A₂, A₃, . . . , A_{N}, respectively. The capacitance of the capacitive load is tuned by controlling the number of turned-on MOS switches. Specifically, by selecting the MOS capacitors through control signals A₁-A_{N}, the capacitive load can be varied, thereby changing the delay from the input IN to the output OUT.

FIG. 5 is a diagram illustrating a second capacitive load tuning design according to an embodiment of the present invention. The tunable delay circuit 302 shown in FIG. 3 may be implemented using the capacitive load tuning circuit 500 shown in FIG. 5. The capacitive load tuning circuit 500 includes a MOS capacitor acting as a capacitive load. The MOS capacitor has a first end coupled to a signal RZ to be delayed (which is not a reference voltage such as a power supply voltage or a ground voltage) and a second end coupled to a control voltage V_{CAP}. The capacitance of the capacitive load is tuned by controlling the control voltage V_{CAP}. When the control voltage V_{CAP} is set by a first reference voltage (e.g., 0V), equivalent capacitance of the MOS capacitor has a first capacitance value C1, as illustrated in sub-diagram (A) of FIG. 5. When the control voltage V_{CAP} is set by a second reference voltage (e.g., 0.9V), equivalent capacitance of the MOS capacitor has a second capacitance value C2 (C2>C1), as illustrated in sub-diagram (B) of FIG. 5. Specifically, by selecting the control voltage V_{CAP} applied to the MOS capacitor, the capacitive load can be varied, thereby changing the delay of the signal RZ.

In some embodiments of the present invention, the delay circuit(s) 108 implemented by reusing the poly gates (OD edge dummy gates) 106_1-106_6 may be used by a DAC application.

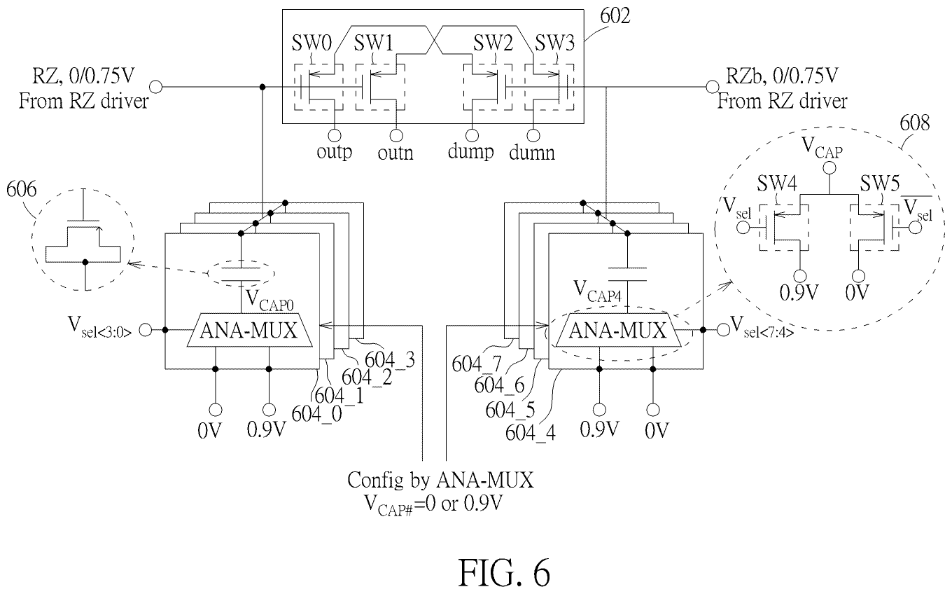

FIG. 6 is a diagram illustrating a DAC cell that receives control signals RZ, RZb with tunable delays set by tunable delay circuits implemented using OD edge dummy gates according to an embodiment of the present invention. The DAC cell 602 of a sub-DAC of a time-interleaved current-steering DAC may have a plurality of return-to-zero (RZ) switches SW0, SW1, SW2, SW3 (which are MOS switches) that are controlled by control signals RZ, RZb for outputting the current of the DAC cell 602 to an output (outp, outn) and a dummy output (dump, dumn) alternatively. Specifically, the control signal RZ determines if the current of the DAC cell 602 is provided to the output (outp, outn), and the control signal RZb determines if the current of the DAC cell 602 is provided to the dummy output (dump, dumn). It should be noted that the DAC cell 602 is shown having only four RZ switches SW0-SW3 for brevity and simplicity. In practice, the DAC cell 602 includes additional circuit elements to achieve its designated functions.

The control signal RZ of the RZ switches SW0, SW1 has a tunable delay controlled by a set of tunable delay circuits 604_0, 604_1, 604_2, 604_3. The control signal RZb of the RZ switches SW2, SW3 has a tunable delay controlled by another set of tunable delay circuits 604_4, 604_5, 604_6, 604_7. In this embodiment, each of the tunable delay circuits 604_0-604_7 acts as a tuning cell, and employs a capacitive load tuning technique. Hence, the principle of each of the tunable delay circuits 604_0-604_7 is the same as that of the capacitive load tuning circuit 500 shown in FIG. 5. As shown in FIG. 6, each of the tunable delay circuits 604_0-604_7 has the same circuit structure, and includes a MOS capacitor 606 and an analog multiplexer (labeled by “ANA-MUX”) 608, where the analog multiplexer 608 is implemented using two MOS switches SW4, SW5 that are controlled by selection signals Vₛₑₗ, V̅ₛ̅ₑ̅ₗ̅. When the MOS switch SW4 is turned on and the MOS switch SW5 is turned off, the control voltage V_{CAP} of the MOS capacitor 606 is set by 0.9V. When the MOS switch SW4 is turned off and the MOS switch SW5 is turned on, the control voltage V_{CAP} of the MOS capacitor 606 is set by 0V. It should be noted that the circuit design of the analog multiplexer 608 shown in FIG. 6 is for illustrative purposes only, and is not meant to be a limitation of the present invention. In practice, the analog multiplexer 608 may be configured to receive a plurality of reference voltages (e.g., two or more reference voltages) and output one of the plurality of reference voltages as the control voltage V_{CAP} of the MOS capacitor 606.

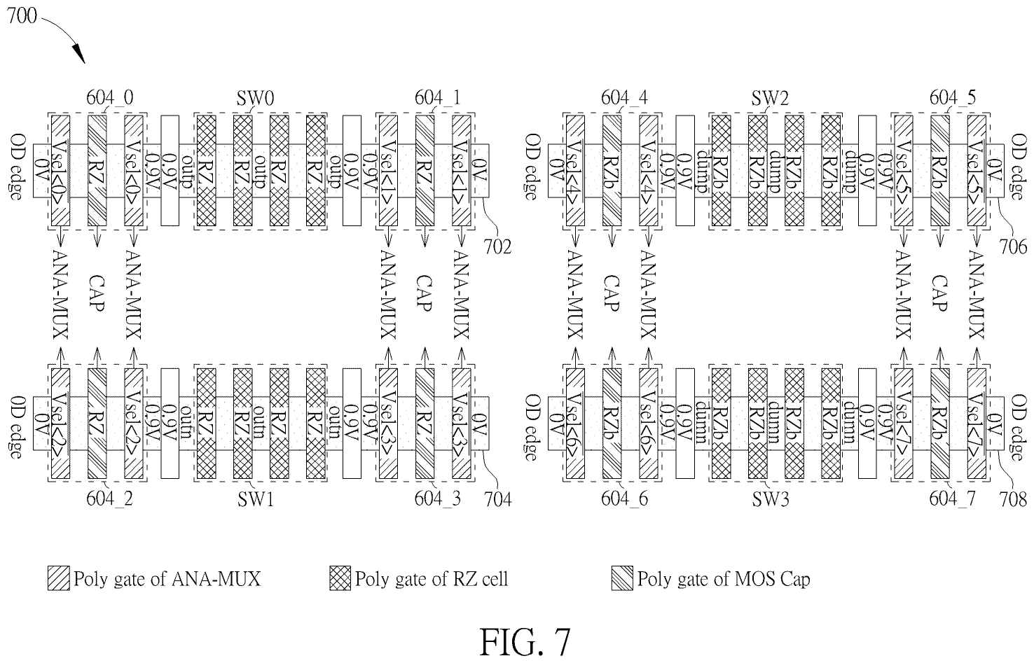

The tunable delay circuits 604_0-604_7 are implemented by reusing OD edge dummy gates. FIG. 7 is a top view of a layout design of RZ switches SW0-SW3 and tunable delay circuits 604_0-604_7 shown in FIG. 6. The semiconductor device 700 includes a plurality of OD areas 702, 704, 706, 708 on an OD layer, and a plurality of poly gates on a poly layer above the OD layer. The poly gates formed above the same OD area 702 include poly gates used by the RZ switch SW0, an OD edge dummy gate used by a MOS capacitor of the tunable delay circuit 604_0, two OD edge dummy gates used by MOS switches of an analog multiplexer of the tunable delay circuit 604_0, an OD edge dummy gate used by a MOS capacitor of the tunable delay circuit 604_1, and two OD edge dummy gates used by MOS switches of an analog multiplexer of the tunable delay circuit 604_1. The poly gates formed above the same OD area 704 include poly gates used by the RZ switch SW1, an OD edge dummy gate used by a MOS capacitor of the tunable delay circuit 604_2, two OD edge dummy gates used by MOS switches of an analog multiplexer of the tunable delay circuit 604_2, an OD edge dummy gate used by a MOS capacitor of the tunable delay circuit 604_3, and two OD edge dummy gates used by MOS switches of an analog multiplexer of the tunable delay circuit 604_3. The poly gates formed above the same OD area 706 include poly gates used by the RZ switch SW2, an OD edge dummy gate used by a MOS capacitor of the tunable delay circuit 604_4, two OD edge dummy gates used by MOS switches of an analog multiplexer of the tunable delay circuit 604_4, an OD edge dummy gate used by a MOS capacitor of the tunable delay circuit 604_5, and two OD edge dummy gates used by MOS switches of an analog multiplexer of the tunable delay circuit 604_5. The poly gates formed above the same OD area 708 include poly gates used by the RZ switch SW3, an OD edge dummy gate used by a MOS capacitor of the tunable delay circuit 604_6, two OD edge dummy gates used by MOS switches of an analog multiplexer of the tunable delay circuit 604_6, an OD edge dummy gate used by a MOS capacitor of the tunable delay circuit 604_7, and two OD edge dummy gates used by MOS switches of an analog multiplexer of the tunable delay circuit 604_7. It should be noted that OD areas 702, 704, 706, 708 include source/drain regions of MOS transistors used by RZ switches SW0-SW3 of DAC cell 602, and further include source/drain regions of MOS transistors used by MOS capacitor 606 and MOS switches SW4, SW5 of each of the tunable delay circuits 604_0-604_7.

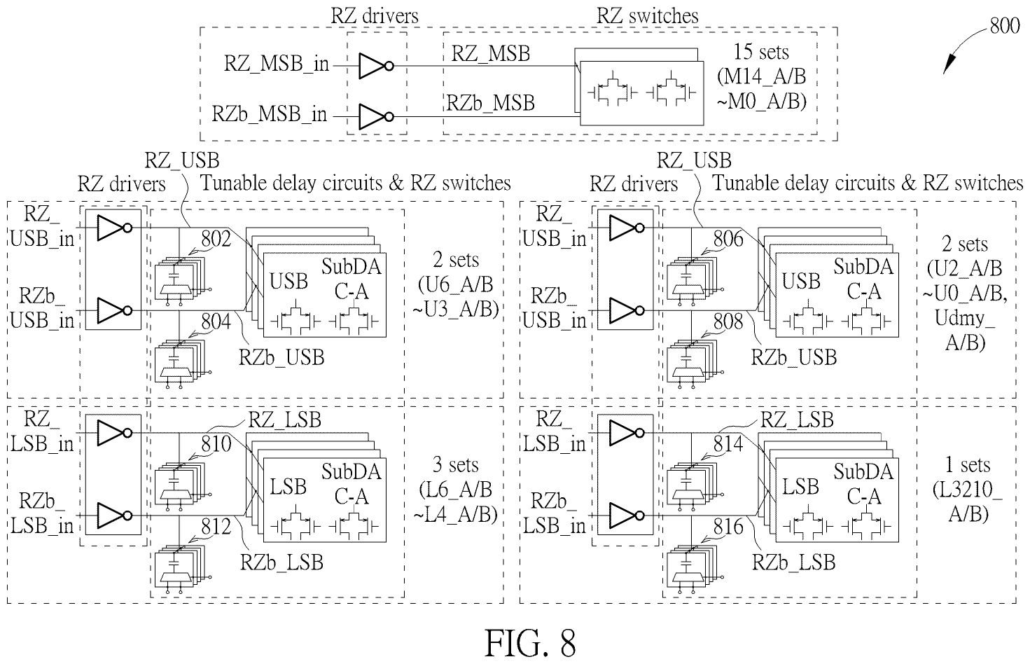

FIG. 8 is a diagram illustrating a sub-DAC with tunable delay circuits implemented using OD edge dummy gates according to an embodiment of the present invention. In this embodiment, the sub-DAC 800 may include DAC cells for dealing with digital-to-analog conversion of an MSB segment, DAC cells for dealing with digital-to-analog conversion of a USB segment, and DAC cells for dealing with digital-to-analog conversion of an LSB segment. As shown in FIG. 8, a delay tuning circuit 802 includes four tunable delay circuits each having a circuit structure the same as that of the tunable delay circuit shown in FIG. 6, and applies a tunable delay to a control signal RZ_USB of RZ switches used by USB6/USB5/USB4/USB3 DAC cell; a delay tuning circuit 804 includes four tunable delay circuits each having a circuit structure the same as that of the tunable delay circuit shown in FIG. 6, and applies a tunable delay to a control signal RZb_USB of RZ switches used by USB6/USB5/USB4/USB3 DAC cell; a delay tuning circuit 806 includes four tunable delay circuits each having a circuit structure the same as that of the tunable delay circuit shown in FIG. 6, and applies a tunable delay to a control signal RZ_USB of RZ switches used by USB2/USB1/USB0 DAC cell; a delay tuning circuit 808 includes four tunable delay circuits each having a circuit structure the same as that of the tunable delay circuit shown in FIG. 6, and applies a tunable delay to a control signal RZb_USB of RZ switches used by USB2/USB1/USB0 DAC cell; a delay tuning circuit 810 includes four tunable delay circuits each having a circuit structure the same as that of the tunable delay circuit shown in FIG. 6, and applies a tunable delay to a control signal RZ_LSB of RZ switches used by LSB6/LSB5/LSB4 DAC cell; a delay tuning circuit 812 includes four tunable delay circuits each having a circuit structure the same as that of the tunable delay circuit shown in FIG. 6, and applies a tunable delay to a control signal RZb_LSB of RZ switches used by LSB6/LSB5/LSB4 DAC cell; a delay tuning circuit 814 includes four tunable delay circuits each having a circuit structure the same as that of the tunable delay circuit shown in FIG. 6, and applies a tunable delay to a control signal RZ_LSB of RZ switches used by LSB3/LSB2/LSB1/LSB0 DAC cell; and a delay tuning circuit 816 includes four tunable delay circuits each having a circuit structure the same as that of the tunable delay circuit shown in FIG. 6, and applies a tunable delay to a control signal RZb_LSB of RZ switches used by LSB3/LSB2/LSB1/LSB0 DAC cell.

In this embodiment, each of the delay tuning circuits 802, 804, 806, 808, 810, 812, 814, 816 has the same number of tunable delay circuits. Hence, each of the delay tuning circuits 802, 804, 806, 808, 810, 812, 814, 816 supports the same delay tuning steps, where a delay tuning step (which may be the order of tens femtoseconds (fs)) is set by the number of MOS capacitors connected to V_{CAP}=0V and the number of MOS capacitors connected to V_{CAP}=0.9V under control of a delay tuning code. Considering a case where a delay tuning circuit includes W tunable delay circuits, a delay tuning code of the delay tuning circuit is selected from {0, 1, . . . , W-1, W}, and is indicative of the number of MOS capacitors connected to V_{CAP}=0.9V. Hence, when the delay tuning code is set by a maximum value W, a maximum delay tuning step is selected by the delay tuning circuit through controlling all of W tunable delay circuits to have W MOS capacitors connected to 0.9V; when the delay tuning code is set by a second maximum value (W-1), a second maximum delay tuning step is selected by the delay tuning circuit through controlling (W-1) tunable delay circuits to have (W-1) MOS capacitors connected to 0.9V and one tunable delay circuit to have a MOS capacitor connected to 0V; when the delay tuning code is set by a second minimum value 1, a second minimum delay tuning step is selected by the delay tuning circuit through controlling one tunable delay circuit to have a MOS capacitor connected to 0.9V and (W-1) tunable delay circuits to have (W-1) MOS capacitors connected to 0V; and when the delay tuning code is set by a minimum value 0, a minimum delay tuning step is selected by the delay tuning circuit through controlling all of W tunable delay circuits to have W MOS capacitors connected to 0V.

In another embodiment, the delay tuning circuits 802, 804, 806, 808, 810, 812, 814, 816 may be modified to have different numbers of tunable delay circuits. For example, one of the delay tuning circuits 802, 804, 806, 808, 810, 812, 814, 816 may include R tunable delay circuits each having a circuit structure the same as that of the tunable delay circuit shown in FIG. 6, and another of the delay tuning circuits 802, 804, 806, 808, 810, 812, 814, 816 may include S (S≠R) tunable delay circuits each having a circuit structure the same as that of the tunable delay circuit shown in FIG. 6. Hence, the delay tuning circuits 802, 804, 806, 808, 810, 812, 814, 816 may include delay tuning circuits that support different delay tuning steps.

In this embodiment, the delay tuning circuits 802, 804, 806, 808, 810, 812, 814, 816 may be categorized into two groups, depending upon routing and placement of the DAC cells. As shown in FIG. 8, the delay tuning circuits 802, 804, 810, 812 are categorized into an L-group, and the delay tuning circuits 806, 808, 814, 816 are categorized into an R-group. As mentioned above, the delay tuning step of one delay tuning circuit is selected by a delay tuning code. The delay tuning code of the L-group and the delay tuning code of the R-group may be set individually. In addition, delay tuning circuits belonging to the same group may be controlled by the same delay tuning code or different delay tuning codes, depending upon actual design considerations. The L-group and the R-group can be tuned individually to compensate for clock/power/output routing-induced skew.

In above embodiments, the proposed delay circuits implemented using OD edge dummy gates are used to address the skew issue of a DAC circuit. However, this is for illustrative purposes only, and is not meant to be a limitation of the present invention. In practice, any circuit using the proposed delay circuits implemented using OD edge dummy gates to solve skew issue and LOD effect simultaneously falls within the scope of the present invention. In addition, the proposed delay circuits implemented using OD edge dummy gates may be tunable delay circuits using the gate delay tuning technique, the capacitive load tuning technique, or any feasible delay tuning technique, depending upon actual design consideration. To put it simply, any semiconductor device that reuses OD edge dummy gates to implement delay circuits falls within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device comprising:
a first oxide diffusion (OD) area;
at least one first poly gate, formed above the first OD area; and
a plurality of second poly gates, formed on both sides of the at least one first poly gate and above the first OD area, wherein the plurality of second poly gates are OD edge dummy gates that are used to reduce length of oxide diffusion (LOD) effect, and at least a portion of the plurality of second poly gates are reused to implement at least one first delay circuit.

2. The semiconductor device of claim 1, wherein the at least one first delay circuit is configured to delay at least one signal to generate at least one delayed signal, and the at least one delayed signal is received by at least one metal-oxide-semiconductor (MOS) transistor using the at least one first poly gate.

3. The semiconductor device of claim 2, wherein the at least one MOS transistor acts as at least one MOS switch controlled by the at least one delayed signal.

4. The semiconductor device of claim 3, wherein the at least one MOS switch is employed by a digital-to-analog converter (DAC) cell.

5. The semiconductor device of claim 1, further comprising:
a second OD area, separated from the first OD area;
at least one third poly gate, formed above the second OD area; and
a plurality of fourth poly gates, formed on both sides of the at least one third poly gate and above the second OD area, wherein the plurality of fourth poly gates are OD edge dummy gates that are used to reduce LOD effect, and at least a portion of the plurality of fourth poly gates are reused to act as at least one second delay circuit.

6. The semiconductor device of claim 5, wherein the at least one first delay circuit is configured to delay at least one first signal to generate at least one first delayed signal, and the at least one first delayed signal is received by at least one first metal-oxide-semiconductor (MOS) transistor using the at least one first poly gate; and the at least one second delay circuit is configured to delay at least one second signal to generate at least one second delayed signal, and the at least one second delayed signal is received by at least one second MOS transistor using the at least one third poly gate.

7. The semiconductor device of claim 6, wherein each of the at least one first delay circuit and the at least one second delay circuit comprises a tunable delay circuit.

8. The semiconductor device of claim 6, wherein the at least one first MOS transistor acts as at least one first MOS switch controlled by the at least one first delayed signal; and the at least one second MOS transistor acts as at least one second MOS switch controlled by the at least one second delayed signal.

9. The semiconductor device of claim 5, wherein the at least one first delay circuit and the at least one second delay circuit are both configured to delay at least one signal to generate at least one delayed signal, and the at least one delayed signal is received by at least one first metal-oxide-semiconductor (MOS) transistor using the at least one first poly gate and at least one second MOS transistor using the at least one third poly gate.

10. The semiconductor device of claim 9, wherein each of the at least one first delay circuit and the at least one second delay circuit comprises a tunable delay circuit.

11. The semiconductor device of claim 9, wherein the at least one first MOS transistor acts as at least one first MOS switch controlled by the at least one delayed signal; and the at least one second MOS transistor acts as at least one second MOS switch controlled by the at least one delayed signal.

12. The semiconductor device of claim 1, wherein the at least one first delay circuit comprises a tunable delay circuit.

13. The semiconductor device of claim 12, wherein the tunable delay circuit employs a gate delay tuning technique.

14. The semiconductor device of claim 12, wherein the tunable delay circuit employs a capacitive load tuning technique.

15. The semiconductor device of claim 14, wherein the tunable delay circuit comprises:
a plurality of capacitors, implemented using OD edge dummy gates; and
a plurality of switches, implemented using OD edge dummy gates, wherein the plurality of switches are connected to the plurality of capacitors, respectively.

16. The semiconductor device of claim 14, wherein the tunable delay circuit further comprises:
a capacitor, implemented using an OD edge dummy gate; and
an analog multiplexer, implemented using OD edge dummy gates, wherein the analog multiplexer is configured to receive a plurality of reference voltages, and output one of the plurality of reference voltages to the capacitor.
